(19) United States
(12) Patent Application Publication
(10) Pub. No.: US 2026/0299951 A1
(43) Pub. Date: Oct. 1, 2026

(54) SIMULATION APPARATUS, SIMULATION METHOD, AND NON-TRANSITORY COMPUTER READABLE MEDIUM

(71) Applicant: Renesas Electronics Corporation, Tokyo (JP)

(72) Inventor: Masahiro DOI, Tokyo (JP)

(21) Appl. No.: 19/447,085

(22) Filed: Jan. 13, 2026

(30) Foreign Application Priority Data
Mar. 25, 2025 (JP) 2025-049141

(51) Int. Cl. G06F 9/30

(52) U.S. Cl. CPC G06F 9/30065

(57) ABSTRACT

A simulation apparatus includes an acquisition unit, a preprocessing unit, and a simulation unit. The acquisition unit acquires an executable file to be verified. The preprocessing unit detects a delay loop instruction sequence included in the executable file to be verified, inserts a specific jump instruction that moves an order of a next instruction to be executed to an instruction following the delay loop instruction sequence before the delay loop instruction sequence to generate an edited executable file, and calculates a processing time required for the delay loop instruction sequence. The simulation unit advances an elapsed time in a simulation by the processing time required for the delay loop instruction sequence when processing the specific jump instruction during an execution of a process based on the edited executable file.

### CROSS-REFERENCE TO RELATED APPLICATIONS

The disclosure of Japanese Patent Application No. 2025-049141 filed on Mar. 25, 2025, including the specification, drawings and abstract is incorporated herein by reference in its entirety.

### BACKGROUND

The present disclosure relates to, for example, a simulation apparatus, a simulation method, and a non-transitory computer readable medium for storing a program.

In recent years, with the evolution of autonomous driving, electrification, and connected technologies, the functionality and performance of in-vehicle electronic control units (ECUs) have significantly advanced. Consequently, the scale and complexity of electronic control software executed in in-vehicle ECUs are also increasing. In the development of in-vehicle software, a method of software operation verification using a simulation apparatus has been introduced to improve development efficiency. The simulation apparatus used here is a development environment that simulates hardware and includes a central processing unit (CPU) model for executing in-vehicle software. Therefore, it is possible to verify the operation of in-vehicle software even at an early stage of development when the actual ECU for executing the in-vehicle software is not yet available.

There are disclosed techniques listed below.

[Patent Document 1] U.S. Patent Application Publication No. 2021/0357549

An example of such a simulation apparatus is, for instance, disclosed in Patent Document 1. Patent Document 1 discloses a simulation apparatus in which a core unit, as a simulation model, executes a target program.

### SUMMARY

The simulation apparatus sequentially executes instructions included in the program of the software to be verified, and the state of the CPU model changes accordingly. The CPU model outputs data such as logs and statuses (hereinafter referred to as execution logs) corresponding to the processing performed by executing instructions. Based on the output execution logs, the operation verification of the software is performed by confirming whether the state transitions of the CPU model are as intended.

Thus, since the operation verification of the software is performed by executing the instructions included in the software program, the longer the program of the software to be verified, the more time the operation verification will require. As mentioned above, due to the increasing scale and complexity of in-vehicle software, there is a demand for reducing the time required for software operation verification using a simulation apparatus.

Other objects and novel features will become apparent from the description of this specification and the accompanying drawings.

A simulation apparatus according to one embodiment includes an acquisition unit, a preprocessing unit and simulation unit. The acquisition unit acquires an executable file to be verified. The preprocessing unit detects a delay loop instruction sequence included in the executable file to be verified, inserts a specific jump instruction that moves an order of a next instruction to be executed to an instruction following the delay loop instruction sequence before the delay loop instruction sequence to generate an edited executable file, and calculates a processing time required for the delay loop instruction sequence. The simulation unit advances an elapsed time in a simulation by the processing time required for the delay loop instruction sequence when processing the specific jump instruction during an execution of a process based on the edited executable file.

According to the present disclosure, the execution time of the simulation can be shortened, and as a result, the time required for software operation verification can be reduced.

### BRIEF DESCRIPTION OF THE DRAWINGS

FIG. 1 is a block diagram illustrating an example of a configuration of a simulation apparatus according to an embodiment.

FIG. 2 is a block diagram illustrating an example of a hardware configuration of the simulation apparatus according to the embodiment.

FIG. 3 is a flowchart illustrating an example of preprocessing in the simulation apparatus according to the embodiment.

FIG. 4 is a diagram illustrating an example of a delay loop instruction sequence according to the embodiment.

FIG. 5 is a diagram illustrating an example of an edited executable file according to the embodiment.

FIG. 6 is a diagram illustrating an example of information recorded in a jump instruction table according to the embodiment.

FIG. 7 is a flowchart illustrating an example of simulation processing in the simulation apparatus according to the embodiment.

### DETAILED DESCRIPTION

The present disclosure is described with reference to several exemplary embodiments. These embodiments are described for illustrative purposes only and are not intended to suggest limitations on the scope of the present disclosure, but rather to assist those skilled in the art in understanding and implementing the disclosure. The disclosure described in this specification can be implemented in various ways other than those described below.

In the following description and claims, unless otherwise defined, all technical and scientific terms used herein have the same meaning as commonly understood by one of ordinary skill in the art to which this disclosure belongs.

Hereinafter, embodiments of the present disclosure will be described with reference to the drawings. It should be noted that each drawing is merely illustrative for explaining one or more embodiments. Each drawing is not associated with only one specific embodiment but may be associated with one or more other embodiments. As will be understood by those skilled in the art, various features or steps described with reference to any one drawing can be combined with features or steps shown in one or more other drawings to create embodiments not explicitly illustrated or described. Not all features or steps shown in any one drawing for describing exemplary embodiments are necessarily essential, and some features or steps may be omitted. The order of steps described in any drawing may be changed as appropriate.

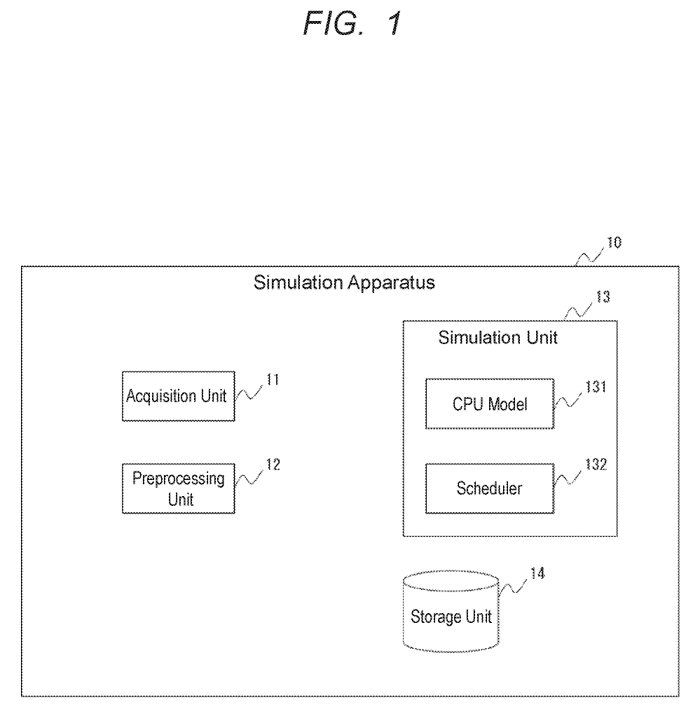

Referring to FIG. 1, the configuration of a simulation apparatus 10 according to an embodiment will be described. FIG. 1 is a block diagram illustrating an example of the configuration of the simulation apparatus 10 according to the embodiment. The simulation apparatus 10 includes an acquisition unit 11, a preprocessing unit 12, a simulation unit 13, and a storage unit 14. Each of these units may be realized by cooperation between one or more programs installed in simulation apparatus 10 and hardware such as the processor and memory of the simulation apparatus 10.

The acquisition unit 11 acquires an executable file to be verified. The preprocessing unit 12 detects a delay loop instruction sequence included in the executable file acquired by the acquisition unit 11. Then, the preprocessing unit 12 inserts a specific jump instruction that moves the order of the next instruction to be executed to the instruction following the delay loop instruction sequence before the delay loop instruction sequence to generate an edited executable file. The preprocessing unit 12 also calculates the processing time required for the delay loop instruction sequence. The preprocessing unit 12 may calculate, as the required processing time, the processing time required for the delay loop instruction sequence when the executable file to be verified is executed by a specific processor.

The simulation unit 13, when processing a specific jump instruction during the execution of simulation processing based on the edited executable file, advances the elapsed time in the simulation by the required processing time calculated by the preprocessing unit 12 and moves the order of the next instruction to be executed to the instruction following the delay loop instruction sequence. The simulation unit 13 includes a CPU model (specific processor model) 131 and a scheduler 132.

The CPU model 131 is a model mounted on a specific device (an actual machine, a device in the actual operational environment) where the executable file to be verified is executed, and for simulating the operation of a specific processor (specific CPU) that executes the executable file to be verified. The CPU model 131 simulates the operation of the specific processor for instructions other than the specific jump instruction.

The scheduler 132 advances the elapsed time in the simulation by the required processing time calculated by the preprocessing unit 12 when the CPU model 131 skips (jumps) the processing of the delay loop instruction sequence. The storage unit 14 stores data of a jump instruction table 601, which will be described later.

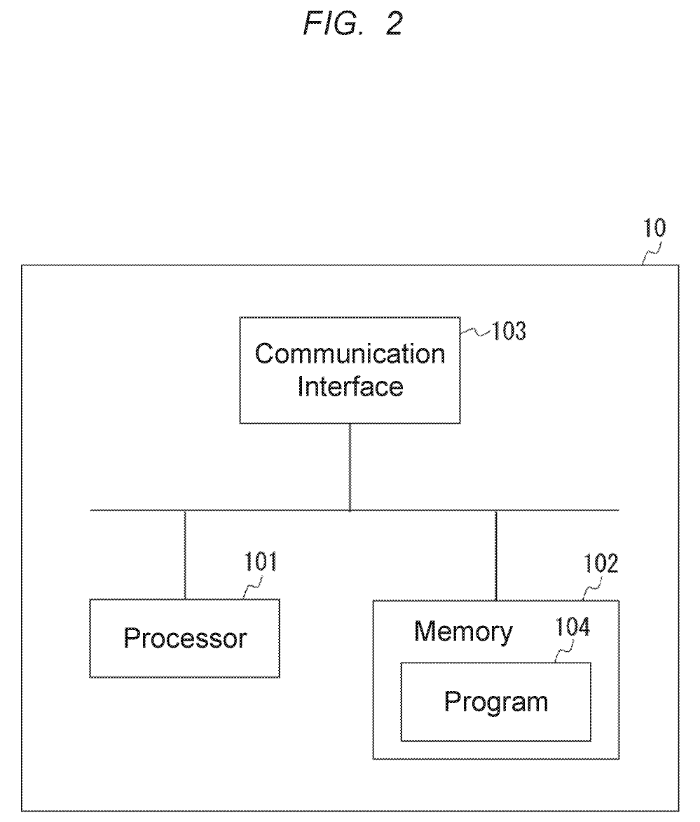

FIG. 2 is a block diagram illustrating an example of the hardware configuration of the simulation apparatus 10 according to the embodiment. In the example of FIG. 2, the simulation apparatus 10 is formed by a computer including a processor 101, a memory 102, and a communication interface 103. The memory 102 stores at least a part of a program 104. The communication interface 103 includes interfaces necessary for communication with other network elements.

When the program 104 is executed by the cooperation of the processor 101 and the memory 102, at least part of the processing of the embodiment is performed by the simulation apparatus 10. For example, each unit shown in FIG. 1 may be realized by the processor 101 reading and executing one or more programs stored in the memory 102. The memory 102 may be of any type. The memory 102 may be, as a non-limiting example, a non-transitory computer readable storage medium. The memory 102 may be implemented using any suitable data storage technology, such as semiconductor-based memory devices, magnetic memory devices, optical memory devices, fixed memory, and removable memory. Although only one memory 102 is shown in the simulation apparatus 10, there may be several physically different memory modules in the simulation apparatus 10. The processor 101 may be of any type. The processor 101 may include microprocessors, digital signal processors, and, one or more processors based on, as a non-limiting example, multicore processor architectures.

The program, when loaded into a computer, includes a set of instructions (or software code) to enable the computer to perform one or more functions described in the embodiment. The program may be stored on non-transitory computer readable media or tangible storage media. By way of example and not limitation, computer readable media or tangible storage media include a Random-Access Memory (RAM), Read-Only Memory (ROM), flash memory, Solid-State Drive (SSD), or other memory technologies, Compact Disc (CD)-ROM, Digital Versatile Disc (DVD), Blu-ray (registered trademark) discs, or other optical disc storage, magnetic cassettes, magnetic tapes, magnetic disk storage, or other magnetic storage devices. The program may also be transmitted over transitory computer readable media or communication media. By way of example and not limitation, transitory computer readable media or communication media include electrical, optical, acoustic, or other forms of propagated signals.

### About Preprocessing

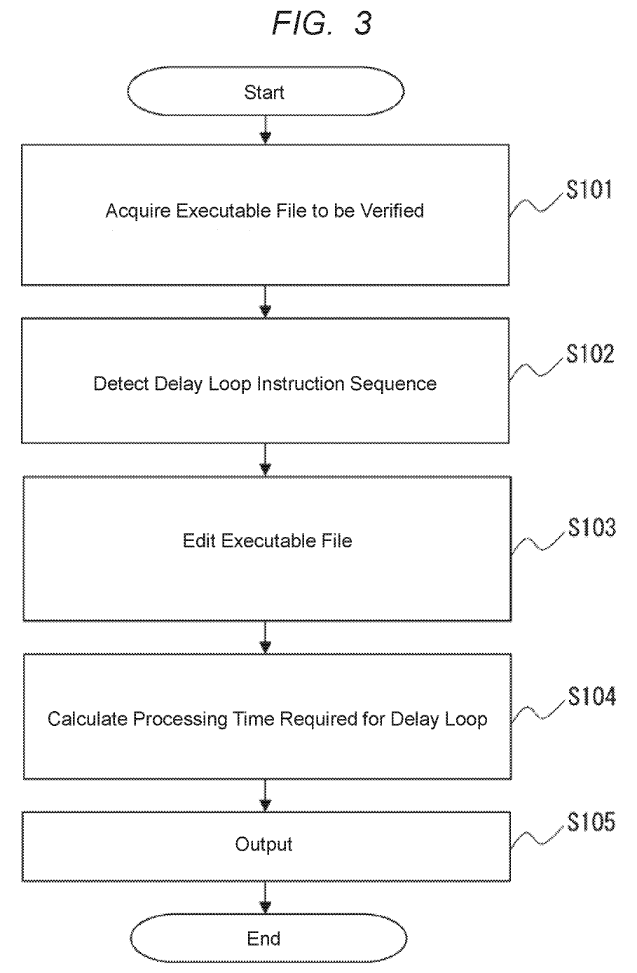

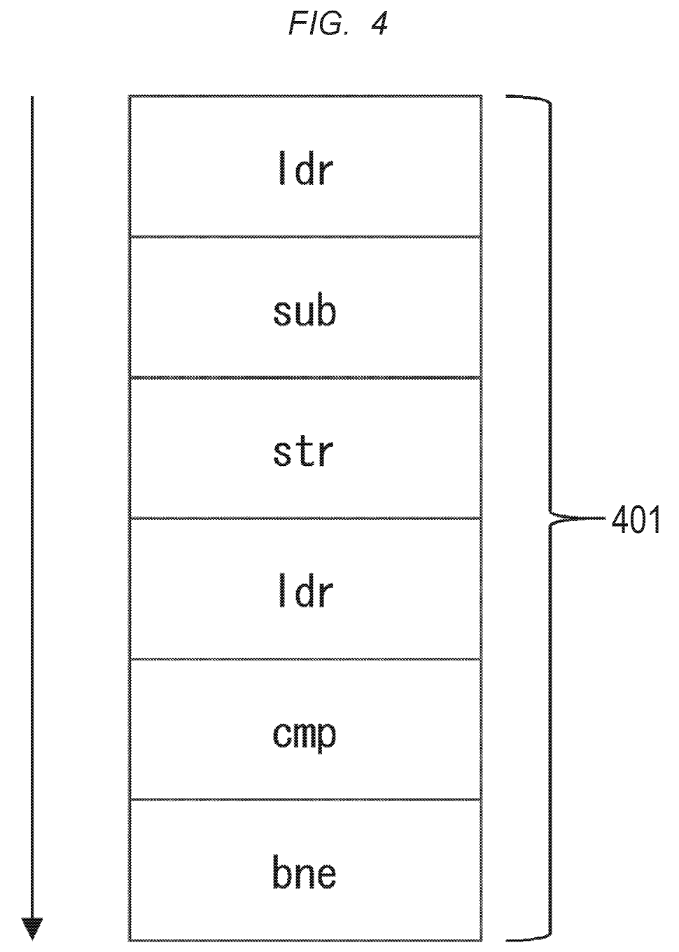

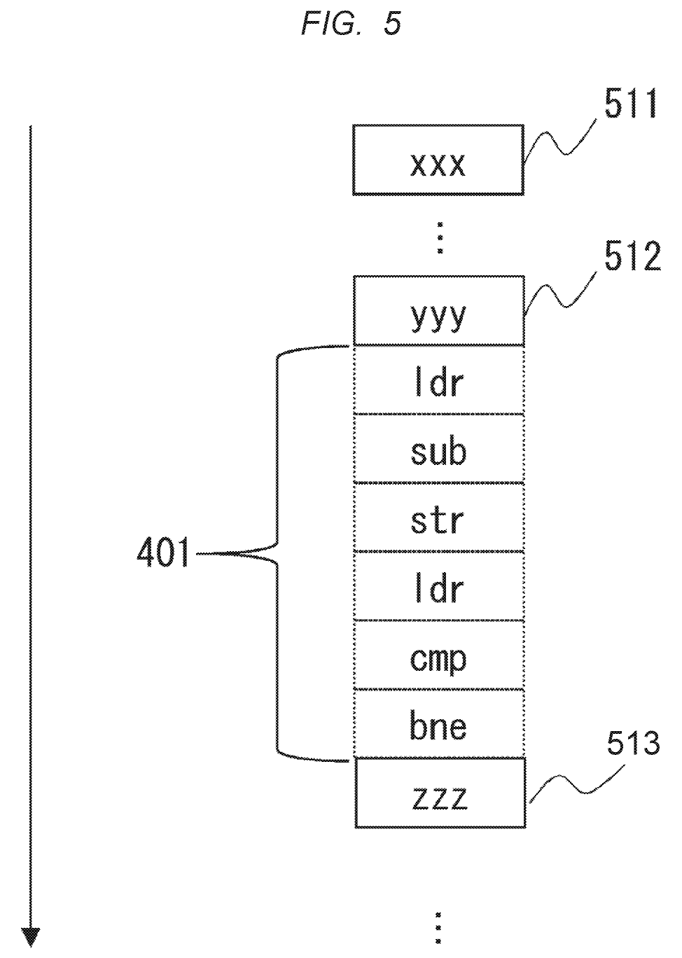

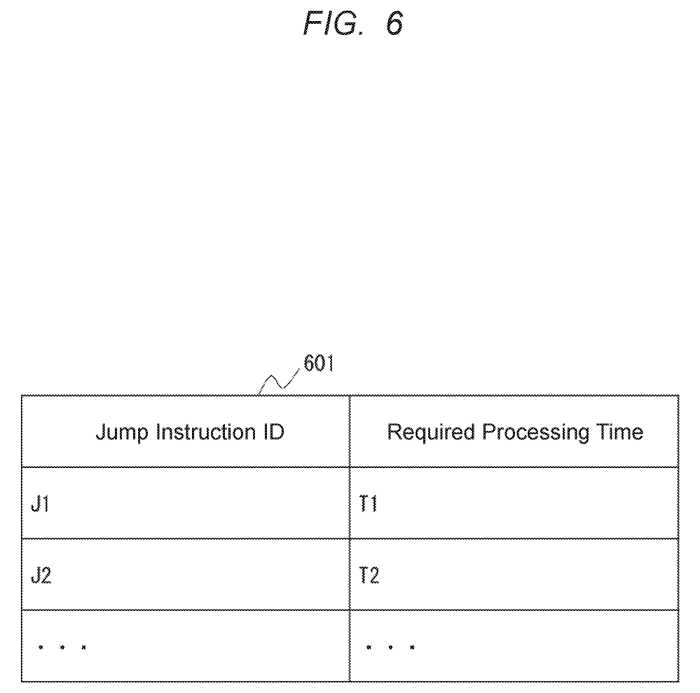

Next, referring to FIGS. 3 - 6, an example of preprocessing in the simulation apparatus 10 according to the embodiment will be described. FIG. 3 is a flowchart illustrating an example of preprocessing in the simulation apparatus 10 according to the embodiment. FIG. 4 is a diagram illustrating an example of a delay loop instruction sequence according to the embodiment. FIG. 5 is a diagram illustrating an example of an edited executable file according to the embodiment. FIG. 6 is a diagram illustrating an example of information recorded in the jump instruction table 601 according to the embodiment. Note that the processing in FIG. 3 may be executed in response to specific operations by an operator (administrator) or the like. FIG. 3 illustrates a specific example of the process by which the preprocessing unit 12 inserts a specific jump instruction before the delay loop instruction sequence to generate an edited executable file.

In a step S101, the acquisition unit 11 acquires the executable file to be verified. The executable file to be verified is an executable file developed to operate a specific device with a specific processor. Note that the executable file is also referred to as a file in an executable state, executable program, file in executable format, binary file, and executable format, among others.

An executable file is a file that includes interpretable instructions for a computer to execute tasks. The instructions may be in machine language (binary code) for a specific processor. The executable file may be generated by a compiler based on source code in a high-level language that is relatively easy for humans to understand.

Subsequently, the preprocessing unit 12 detects the delay loop instruction sequence included in the executable file acquired by the acquisition unit 11 (step S102). The delay loop instruction sequence is, for example, an instruction sequence (instruction group) that may be omitted in simulation for the purpose of verifying the operation of a specific processor based on the executable file. The delay loop instruction sequence may, for example, include only instructions that do not cause the specific processor to perform specific processing (for example, recording data to a specific address range in a register, cache memory, or main memory, etc.). In this case, the delay loop instruction sequence may be an instruction sequence that creates a wait state for other threads or processes performing parallel processing to wait for the completion of state transitions when the specific processor performs state transitions internally. The executable file may include one or more delay loop instruction sequences, and one or more delay loop instruction sequences may be detected in the step S102. Additionally, the delay loop instruction sequence may include multiple types. In this case, each type of delay loop instruction sequence may differ in its instruction sequence content and in the processing time required for that instruction sequence.

FIG. 4 shows an example of a delay loop instruction sequence according to the embodiment. In the example of FIG. 4, the delay loop instruction sequence 401 includes six instructions in the order of ldr, sub, str, ldr, cmp, bne. The ldr is an instruction to read a value from memory and store it in the CPU's general-purpose register. The sub is an instruction to perform subtraction of two values and store the result in the CPU's general-purpose register. The str is an instruction to read a value from the CPU's general-purpose register and store it in memory. The cmp is an instruction to compare two values and set the flags in the CPU's status register based on the result. The bne is an instruction to branch to a certain instruction if the flag in the CPU's status register is 0.

The process of repeating the delay loop instruction sequence 401 N (N is an integer of 1 or more) times is described below. The ldr instruction reads the loop count N from memory and stores it in the general-purpose register of the specific processor. Then, the sub instruction subtracts 1 from N, and the result of the operation, N-1, is stored in the general-purpose register of the specific processor.

Then, the str instruction reads N-1 from the general-purpose register of the specific processor and stores it in memory. Then, the ldr instruction reads N-1 from memory and stores it in the general-purpose register of the specific processor.

Then, the cmp instruction compares N-1 and 0; if the comparison result is a mismatch, the flag in the status register of the specific processor is set to 0, and if the comparison result is a match, the flag in the status register of the specific processor is set to 1.

Then, the bne instruction reads the flag information from the status register; if the flag is 0, it returns the process order to the first ldr instruction, and if the flag is 1, it proceeds to the next instruction. Since the result of the operation is decremented by 1 each time the sub instruction is executed, the result eventually converges to 0, the status register of the specific processor becomes 1 by the cmp instruction, and the loop is exited by the bne instruction.

Subsequently, the preprocessing unit 12 inserts a specific jump instruction that moves the order of the next instruction to be executed by the simulation unit 13 to the instruction following the delay loop instruction sequence before each delay loop instruction sequence, thereby generating an edited executable file (step S103). The specific jump instruction is an instruction specific to the CPU model 131 and may be an instruction that cannot be executed (unsupported) by the specific processor of the actual machine.

Here, as shown in FIG. 5, the preprocessing unit 12 inserts a specific jump instruction 512 before (immediately before) the delay loop instruction sequence 401 in the instruction sequence starting with instruction 511 included in the executable file acquired by the acquisition unit 11. The specific jump instruction 512 is inserted to avoid executing the optional instruction sequence, and in the example of FIG. 5, it is an instruction to skip the process order to the instruction 513 immediately after the delay loop instruction sequence 401.

Additionally, the preprocessing unit 12 calculates the processing time required for each delay loop instruction sequence by the specific processor (step S104). Here, the preprocessing unit 12 estimates the processing time when the specific processor processes each delay loop instruction sequence. In this case, the preprocessing unit 12 may, for example, calculate the product of the time required for the specific processor to process the six instructions included in the delay loop instruction sequence and the loop count N specified in the delay loop instruction sequence as the processing time required for the delay loop instruction sequence by the specific processor.

The time required for the specific processor to process the six instructions included in the delay loop instruction sequence may be the total value of the specification values for the processing time required for each instruction included in the delay loop instruction sequence. The total value may be set (registered) in advance in the simulation apparatus 10 by an operator or the like. The specification values for the processing time required for each instruction may be known in advance to the operator or the like by the developer of the specific processor.

Additionally, the preprocessing unit 12 may acquire the loop count N specified in the delay loop instruction sequence from the memory address specified by the ldr instruction included in the delay loop instruction sequence. Note that the order of the processing in the step S103 and the processing in the step S104 may be either way, or they may be executed in parallel.

The preprocessing unit 12 may record the processing time required for each delay loop instruction sequence by the specific processor in the jump instruction table 601. In the example of FIG. 6, the required processing time is recorded in the jump instruction table 601 in association with the jump instruction ID. The jump instruction ID is the identification information of the specific jump instruction inserted before the delay loop instruction sequence. Additionally, the required processing time is the time required for the specific processor to process the delay loop instruction sequence.

Subsequently, the preprocessing unit 12 outputs the edited executable file and the information indicating the processing time required for each delay loop instruction sequence to the simulation unit 13 via the storage unit 14 (step S105).

### About Simulation Processing

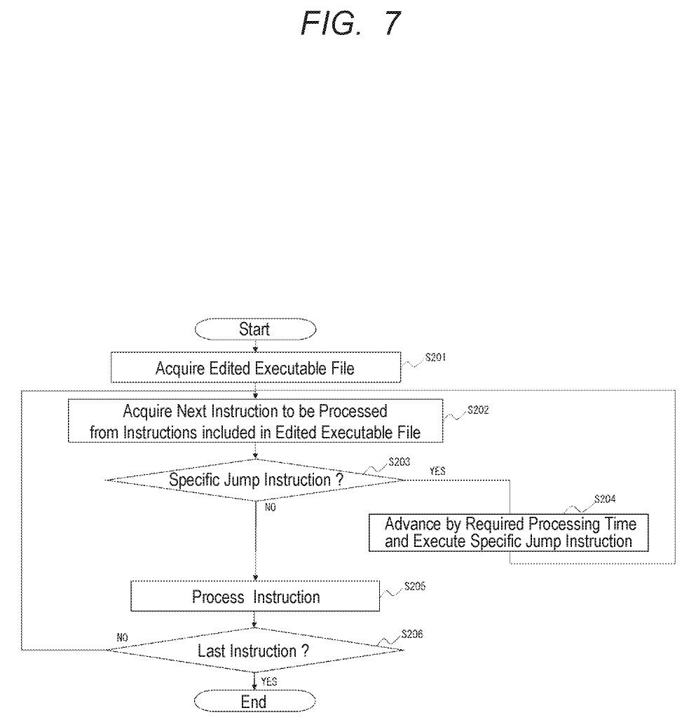

Next, referring to FIG. 7, an example of the simulation processing in the simulation apparatus 10 according to the embodiment will be described. FIG. 7 is a flowchart illustrating an example of the simulation processing in the simulation apparatus 10 according to the embodiment. Note that the processing in FIG. 7 may, for example, be executed in response to specific operations performed by an operator (administrator) or the like. FIG. 7 illustrates a specific example of simulation processing performed by the simulation unit 13 based on the edited executable file.

In a step S201, the simulation unit 13 acquires the edited executable file generated by the preprocessing unit 12 and executes it on the CPU model 131.

Subsequently, the CPU model 131 acquires the next instruction to be processed (target instruction) from among the instruction sequence included in the edited executable file (step S202).

Subsequently, the CPU model 131 determines whether the target instruction is a specific jump instruction (step S203). If the target instruction is not a specific jump instruction (NO in the step S203), proceed to a step S205. On the other hand, if the target instruction is a specific jump instruction (YES in the step S203), the CPU model 131 advances the elapsed time in the simulation by the required processing time recorded in the jump instruction table 601, executes the specific jump instruction (step S204), and proceeds to the step S202.

Here, the CPU model 131 may, for example, execute the Application Programming Interface (API) of the scheduler 132 using the jump instruction ID included in the specific jump instruction as an argument. Then, the scheduler 132 may refer to the jump instruction table 601 and acquire the required processing time associated with the jump instruction ID specified by the argument. As a result, the CPU model 131 can advance the simulation time by an amount similar to the processing time required for the delay loop instruction sequence by the specific processor. Note that the CPU model 131 may output the elapsed simulation time at the point when each instruction is processed, for instance, in a log file or similar.

Furthermore, when a specific jump instruction is executed, the order of the next instruction to be executed is moved to the instruction following the delay loop instruction sequence. More specifically, if the target instruction is a specific jump instruction, as shown in FIG. 5, the next target instruction after the specific jump instruction 512 becomes the instruction 513 following the delay loop instruction sequence 401. Therefore, the CPU model 131 can avoid executing the processing of the delay loop instruction sequence 401. Thus, the simulation execution time can be shortened, resulting in a reduction in the software operation verification time.

Subsequently, the CPU model 131 processes the target instruction (step S205). Subsequently, the CPU model 131 determines whether the target instruction is the last instruction in the instruction sequence included in the edited executable file (step S206). If the target instruction is not the last instruction (NO in the Step s206), proceed to the step S202. On the other hand, if the target instruction is the last instruction (YES in the step S206), the process is terminated.

### Modified Example

The simulation apparatus 10 may be an apparatus contained within a single housing, but the simulation apparatus 10 of this disclosure is not limited to this. Each component of the simulation apparatus 10 may be implemented by cloud computing configured with one or more computers, for example. Such a simulation apparatus 10 is also included as an example of the 'simulation apparatus' of the present disclosure.

The disclosure has been described with reference to embodiments, but it is not limited to the aforementioned embodiments. Various changes can be made to the configuration and details of this disclosure within the scope of the disclosure as understood by those skilled in art. Furthermore, each embodiment can be appropriately combined with other embodiments.

What is claimed is:

1. A simulation apparatus comprising:
an acquisition unit that acquires an executable file to be verified;
a preprocessing unit that detects a delay loop instruction sequence included in the executable file to be verified, inserts a specific jump instruction that moves an order of a next instruction to be executed to an instruction following the delay loop instruction sequence before the delay loop instruction sequence to generate an edited executable file, and calculates a processing time required for the delay loop instruction sequence; and
a simulation unit that advances an elapsed time in a simulation by the processing time required for the delay loop instruction sequence when processing the specific jump instruction during an execution of a process based on the edited executable file.

2. The simulation apparatus according to claim 1,
wherein the simulation unit includes a Central Processing Unit (CPU) model that simulates an operation of a specific CPU by executing the edited executable file, and
wherein the CPU model comprises a model associated with the specific CPU that executes the executable file to be verified.

3. The simulation apparatus according to claim 2, wherein the delay loop instruction sequence comprises an instruction sequence that does not cause state transitions in the specific CPU.

4. The simulation apparatus according to claim 1, wherein the preprocessing unit calculates, as the processing time required for the delay loop instruction sequence, a product of a total value of specification values for a processing time required for each instruction included in the delay loop instruction sequence and a loop count specified in the delay loop instruction sequence.

5. The simulation apparatus according to claim 1,
wherein the delay loop instruction sequence comprises a first delay loop instruction sequence,
wherein the specific jump instruction comprises a first specific jump instruction,
wherein the preprocessing unit detects a second delay loop instruction sequence included in the executable file to be verified, inserts a second specific jump instruction that moves an order of a next instruction to be executed to an instruction following the second delay loop instruction sequence before the second delay loop instruction sequence to generate the edited executable file, and calculates a processing time required for the second delay loop instruction sequence, and
wherein the simulation unit advances the elapsed time in the simulation by the processing time required for the second delay loop instruction sequence when processing the second specific jump instruction during the execution of the process based on the edited executable file.

6. The simulation apparatus according to claim 5,
wherein the first specific jump instruction includes a first jump instruction ID which is identification information of the first specific jump instruction,
wherein the second specific jump instruction includes a second jump instruction ID which is identification information of the second specific jump instruction,
wherein the simulation apparatus comprises a storage unit for storing a jump instruction table,
wherein the preprocessing unit records the processing time required for the first delay loop instruction sequence in the jump instruction table in association with the first jump instruction ID, and records the processing time required for the second delay loop instruction sequence in the jump instruction table in association with the second jump instruction ID, and
wherein the simulation unit advances the elapsed time in the simulation by the processing time required for the first and second delay loop instruction sequences by referring to the jump instruction table when processing the first and second specific jump instructions during the execution of the process based on the edited executable file.

7. A simulation method executed in a simulation apparatus, comprising:
acquiring an executable file to be verified;
detecting a delay loop instruction sequence included in the executable file to be verified, inserting a specific jump instruction that moves an order of a next instruction to be executed to an instruction following the delay loop instruction sequence before the delay loop instruction sequence to generate an edited executable file, and calculating a processing time required for the delay loop instruction sequence; and
advancing an elapsed time in a simulation by the processing time required for the delay loop instruction sequence when processing the specific jump instruction during an execution of a process based on the edited executable file.

8. The simulation method according to claim 7,
wherein the simulation apparatus includes a CPU model associated with a specific CPU that executes the executable file to be verified, and
wherein the simulation method comprises simulating an operation of the specific CPU by executing the edited executable file on the CPU model.

9. The simulation method according to claim 8, wherein the delay loop instruction sequence comprises an instruction sequence that does not cause state transitions in the specific CPU.

10. The simulation method according to claim 7, wherein the calculating the processing time required for the delay loop instruction sequence includes calculating, as the processing time required for the delay loop instruction sequence, a product of a total value of specification values for a processing time required for each instruction included in the delay loop instruction sequence and a loop count specified in the delay loop instruction sequence.

11. The simulation method according to claim 7,
wherein the delay loop instruction sequence comprises a first delay loop instruction sequence,
wherein the specific jump instruction comprises a first specific jump instruction, and
wherein the simulation method comprises:
detecting a second delay loop instruction sequence included in the executable file to be verified, and inserting a second specific jump instruction that moves an order of a next instruction to be executed to an instruction following the second delay loop instruction sequence before the second delay loop instruction sequence to generate the edited executable file;
calculating a processing time required for the second delay loop instruction sequence; and
advancing the elapsed time in the simulation by the processing time required for the second delay loop instruction sequence when processing the second specific jump instruction during the execution of the process based on the edited executable file.

12. The simulation method according to claim 11,
wherein the first specific jump instruction comprises a first jump instruction ID which is identification information of the first specific jump instruction,
wherein the second specific jump instruction comprises a second jump instruction ID which is identification information of the second specific jump instruction,
wherein the simulation apparatus includes a storage unit for storing a jump instruction table,
wherein the simulation method comprises recording the processing time required for the first delay loop instruction sequence in the jump instruction table in association with the first jump instruction ID, and recording the processing time required for the second delay loop instruction sequence in the jump instruction table in association with the second jump instruction ID,
wherein the advancing the processing time required for the first delay loop instruction sequence includes advancing the elapsed time in the simulation by the processing time required for the first delay loop instruction sequence by referring to the jump instruction table, and
wherein the advancing the processing time required for the second delay loop instruction sequence includes advancing the elapsed time in the simulation by the processing time required for the second delay loop instruction sequence by referring to the jump instruction table.

13. A non-transitory computer readable medium storing a program that causes a simulation apparatus to execute a simulation method, the simulation method includes:
acquiring an executable file to be verified;
detecting a delay loop instruction sequence included in the executable file to be verified, inserting a specific jump instruction that moves an order of a next instruction to be executed to the an instruction following the delay loop instruction sequence before the delay loop instruction sequence to generate an edited executable file, and calculating a processing time required for the delay loop instruction sequence; and
advancing an elapsed time in a simulation by the processing time required for the delay loop instruction sequence when processing the specific jump instruction during an execution of a process based on the edited executable file.

14. The non-transitory computer readable medium according to claim 13,
wherein the simulation apparatus includes a CPU model associated with a specific CPU that executes the executable file to be verified, and
wherein the simulation method includes simulating an operation of the specific CPU by executing the edited executable file on the CPU model.

15. The non-transitory computer readable medium according to claim 14, wherein the delay loop instruction sequence comprises an instruction sequence that does not cause state transitions in the specific CPU.

16. The non-transitory computer readable medium according to claim 13, wherein calculating the processing time required for the delay loop instruction sequence includes calculating, as the processing time required for the delay loop instruction sequence, a product of a total value of specification values for a processing time required for each instruction included in the delay loop instruction sequence and a loop count specified in the delay loop instruction sequence.

17. The non-transitory computer readable medium according to claim 13,
wherein the delay loop instruction sequence comprises a first delay loop instruction sequence,
wherein the specific jump instruction comprises a first specific jump instruction,
wherein the simulation method includes:
detecting a second delay loop instruction sequence included in the executable file to be verified, and inserting a second specific jump instruction that moves an order of a next instruction to be executed to an instruction following the second delay loop instruction sequence before the second delay loop instruction sequence to generate the edited executable file;
wherein calculating a processing time required for the second delay loop instruction sequence; and
wherein advancing the elapsed time in the simulation by the processing time required for the second delay loop instruction sequence when processing the second specific jump instruction during the execution of the process based on the edited executable file.

18. The non-transitory computer readable medium according to claim 17,
wherein the first specific jump instruction comprises a first jump instruction ID which is identification information of the first specific jump instruction,
wherein the second specific jump instruction comprises a second jump instruction ID which is identification information of the second specific jump instruction,
wherein the simulation apparatus includes a storage unit for storing a jump instruction table,
wherein the simulation method includes recording the processing time required for the first delay loop instruction sequence in the jump instruction table in association with the first jump instruction ID, and recording the processing time required for the second delay loop instruction sequence in the jump instruction table in association with the second jump instruction ID,
wherein the advancing the processing time required for the first delay loop instruction sequence includes advancing the elapsed time in the simulation by the processing time required for the first delay loop instruction sequence by referring to the jump instruction table, and
wherein the advancing the processing time required for the second delay loop instruction sequence includes advancing the elapsed time in the simulation by the processing time required for the second delay loop instruction sequence by referring to the jump instruction table.
